(19) United States
(12) Patent Application Publication
(10) Pub. No.: US 2017/0199784 A1
(43) Pub. Date: Jul. 13, 2017

(54) METHOD OF DATA RECOVERY WHEN ERRORS FAILING TO BE CORRECTED THROUGH ECC OCCUR TO NAND FLASH

(71) Applicant: Fangxiao FU, Beijing (CN)

(72) Inventor: Fangxiao FU, Beijing (CN)

(21) Appl. No.: 15/318,948

(22) PCT Filed: Jan. 31, 2016
(86) PCT No.: PCT/CN2016/073008

§ 371 Date: Dec. 14, 2016

(30) Foreign Application Priority Data
Jul. 12, 2015 (CN) 201510403709.0

(51) Int. Cl. G06F 11/10; G11C 16/34; G11C 16/26; G11C 29/52; G11C 11/56

(52) U.S. Cl. CPC G06F 11/1072; G11C 29/52; G11C 11/5642; G11C 16/26; G11C 16/3495

(57) ABSTRACT

The method of data recovery when errors failing to be corrected through ECC occur to NAND FLASH includes reading NAND FLASH; setting the read page as a current page; and judging whether the bit errors of the current page can be corrected through ECC. If yes, the operation of reading NAND FLASH is finished. If no, the data of lower pages of the current page is read out and subjected to ECC and information is recorded. Then, the data of the current page is modified according to the bit flipping information of the lower pages of the current page and re-subjecting the current page to ECC verification. The present invention can recover most of the data when errors failing to be corrected through ECC occur to NAND FLASH through the above way.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

1. Field of the Invention

The present invention relates to the memorizing technology field, especially to the field of data recovery of NAND of MLC, TLC and QLC, etc.

2. Description of Related Art Including Information Disclosed Under 37 CFR 1.97 and 37 CFR 1.98.

Common SLC NAND=Single-Level Cell, i.e. 1 bit/cell.

MLC NAND=Multi-Level Cell, i.e. 2 bit/cell, having general speed, general life and general price, with a life of about 3,000-10,000 rewritings. We call the two pages corresponding to each CELL low page and up page.

TLC NAND=Trinary-Level Cell, i.e. 3 bit/cell, also called 8LC by some NAND FLASH manufacturers, having a slow speed and a short life, as well as a cheap price, with a life of about 500-1,000 rewritings. We call the three pages corresponding to each CELL low page, middle page and up page.

QLC NAND=Quad−Level Cell architecture and appearance, i.e. 4 bit/cell. We call the four pages corresponding to each CELL low page, second low page, middle page and up page.

Compared with SLC, MLC, TLC and QLC are characterized by large capacity, low cost, instable memorizing and large error probability, needing to correct errors before use. Large-capacity MLC, TLC and QLC NAND generally adopts error correcting code (ECC) code which can correct errors to guarantee completeness of data memorized.

### BRIEF SUMMARY OF THE INVENTION

The present invention provides a method of data recovery for NAND FLASH, aiming to solve the problem of data recovery when errors failing to be corrected through ECC occur to NAND data.

The technical solution of the present invention to solve above technical problem is as follows: a method of data recovery when errors failing to be corrected through ECC occur to NAND FLASH, comprising:

reading NAND FLASH;

setting the read page as a current page, judging whether the bit errors of the current page can be corrected through ECC, if yes, the operation of reading NAND FLASH is finished, if no, the lower pages of current page are read out and subjected to ECC and bit flipping information is recorded; then modifying the bits of the current page according to the bit flipping information of the lower pages;

re-subjecting the current page to ECC verification.

The advantageous effects of the present invention are effectively prolonging life of NAND FLASH, and lowering probability of error for reading NAND FLASH

In the present invention, through reading NAND FLASH, if the reading operation is found unable to correct all the bit flipping errors in the current page through ECC, the lower pages of the current page are read out to be subjected to ECC error correction, then the bit flipping information is recorded, and the bits corresponding to the current page are modified according to the bit flipping information of the lower pages. The above method can recover the data when errors failing to be corrected through ECC occur to NAND FLASH.

Based on above technical solution, the present invention can be modified as follows:

further, in the NAND FLASH, each CELL stores data of equal to or greater than 2 bits, the binary upper data belongs to lower page and binary lower data belongs to the upper page.

further, when the data of current page is being modified according to the bits flipping information of the lower pages, the value of the bit corresponding to the current page is set as 1 if the binary correct value of lower pages is smaller than the error value, and the value of the bit corresponding to the current page is set as 0 if the binary correct value of lower pages is greater than the error value.

### BRIEF DESCRIPTION OF THE SEVERAL VIEWS OF THE DRAWINGS

FIG. 1 is a flow chart of the method of data recovery as described in the embodiment of the present invention;

FIG. 2 is a flow chart for one embodiment of the method of data recovery.

### DETAILED DESCRIPTION OF THE INVENTION

The principle and features of the present invention will become apparent from the following detailed description of the present invention when considered in conjunction with the drawings. The example illustrated is intended only for explanation purpose and is not the only embodiment in which the present invention may reside.

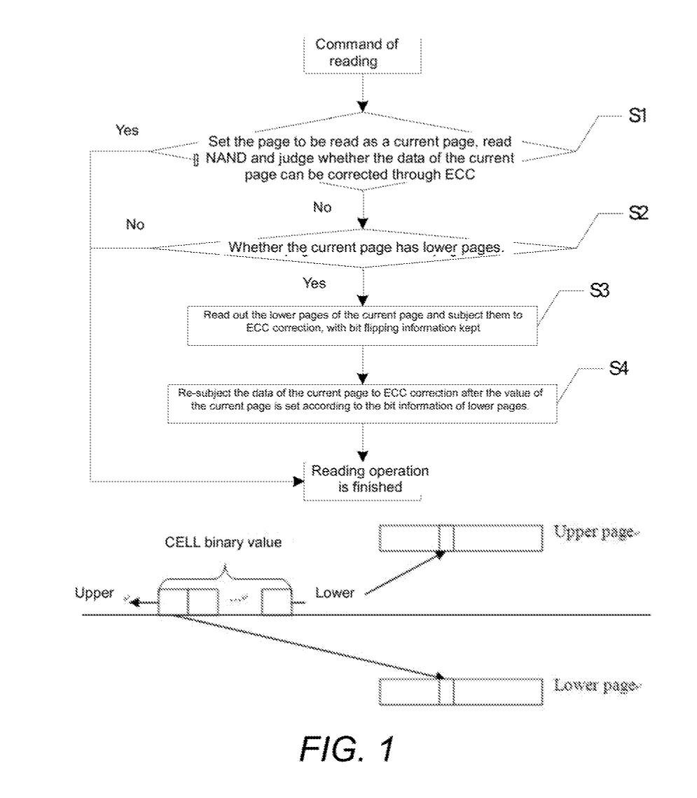

As shown in FIG. 1, the embodiment proposes a method of data recovery when errors failing to be corrected through ECC occur to NAND FLASH to solve the unreliability of data memorizing in NAND of MLC, TLC and QLC etc.

and the method comprises:

S1. NAND receiving coming of the reading operation, setting the page to be read as a current page, reading NAND, judging whether the data of the current page can be corrected through ECC, if yes, the operation of reading NAND FLASH is finished, if no, executing S2.

S2. Judging whether the current page has lower pages, if yes, executing

S3, if no, exiting directly;

S3. Reading out the lower pages of the current page and conducting ECC error correction, keeping bit flipping information;

S4. Re-subjecting the data of the current page to ECC error correction after the value of the current page is set according to the bit flipping information of the lower pages.

If error correction fails, returning to S3 to retry for N times, N being an empiric value configured.

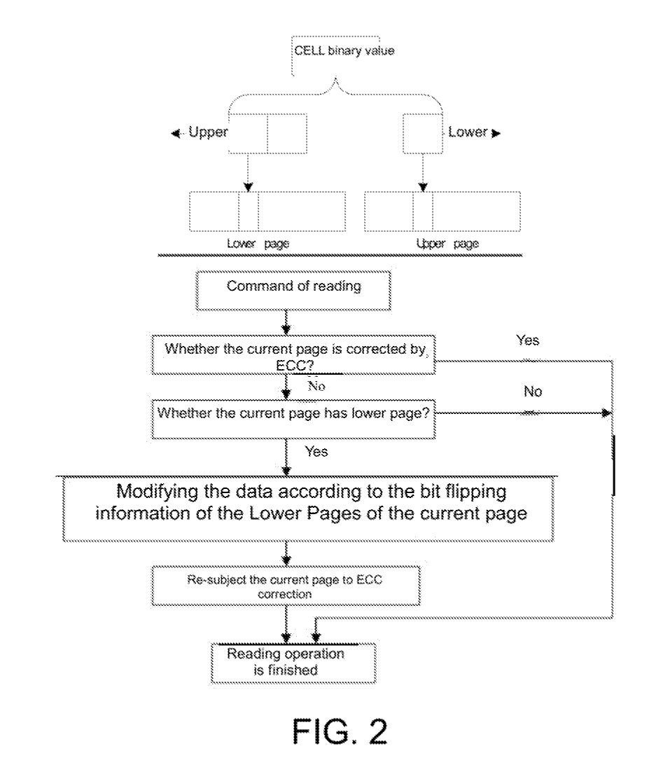

As shown in FIG. 2, analysis found one memory unit for NAND of MLC, TLC and QLC etc. is called a CELL, which can store information of equal to or more than 2 bits. These bit information respectively belongs to different pages. The binary upper data belongs to the lower page and the binary lower data belongs to the upper page.

The lower page and the upper page are relative herein. For example, in QLC NAND, a second low page is an upper page relative to low page, but the second low page is a lower page relative to a middle page, while the low page, the second low page, the middle page and the up page refer to the pages of the same type instead of relative concepts.

For NAND FLASH, the probability of the difference between the error value and the correct value being relatively small is relatively large if an error occurs to the CELL. For example, the correct value of one CELL is 2, and then the probability of it jumping to 1 is larger than jumping to 0. For another example, the correct value of one CELL is 1, and then the probability of it jumping to 2 is larger than jumping to 3 in decimal format. For such case, the probability of correctness by directly setting the lower value is relatively large when the jumping condition of the binary upper of CELL has already been determined. For example, for MLC NAND, if the bit corresponding to the lower page is found to change from correct 0 to wrong 1, then the correct value of the whole CEEL may be binary 00 or 01. Obviously, 01 is closer to the error value 10 or 11, so the value of the bit corresponding to the upper page is directly set as 1. For another example, for TLC, supposing the value of 2 bits at upper changes from correct 01 to wrong 10, then the correct value may be 010 or 011. 011 is closer relative to either error value 100 or 101, so the bit corresponding to the upper page is directly set as 1.

For TLC NAND, if an error failing to be corrected through ECC occurs simultaneously to an up page and a middle page, the data of the middle page is first recovered according to bit flipping information of low page, and then the data of up page is recovered. Similarly, if ECC failing to correct errors occurs simultaneously to an up page, a middle page and a second low page of QLC NAND, the data of the second low page and the middle page is first recovered using the same method, and the data of up page is finally recovered.

The reader will appreciate that the reference terms such as “one embodiment”, “some embodiments”, “example”, “particular example”, or “some examples”, etc. in the present description are intended to mean the particular features, structure, material or characteristics described in connection with this embodiment or example are included in at least one embodiment or example of the present invention. In the description, the illustrative expression for above terms does not need to be for the same embodiment or example. Furthermore, the particular features, structures, materials or characteristics may be combined in any suitable manner in one or more embodiments or examples. In addition, those skilled in the art can combine or group different embodiments or examples and the features of different embodiments or examples, described herein, provided there is no conflict.

While the embodiment of the present invention has been described and illustrated, it is to be understood that the foregoing embodiment is illustrative and in no way to be construed as limiting of the invention. Those of ordinary skill in the art may change, alter, substitute and transform the foregoing embodiment within the scope of the present invention.

1. A method of data recovery when errors failing to be corrected through ECC occur to NAND FLASH, the method comprising the steps of:
reading a NAND FLASH;
setting a read page as a current page;
judging whether bit errors of said current page are to be corrected through ECC;
finishing the step of reading, when said bit errors are to be corrected through ECC;
reading out lower pages of said current page to conduct ECC and recording the bit flipping information, when said bit errors are not to be corrected through ECC;
modifying the bits of said current page according to said bit flipping information of said lower pages; and
re-subjecting said current page to the ECC verification.

2. The method of data recovery, according to claim 1, wherein each CELL stores data of equal to or greater than 2 bits, in said NAND FLASH, the binary upper data belonging to said lower page, and wherein binary lower data belongs to the upper page.

3. The method of data recovery, according to claim 2, further comprising the steps of:
setting a value of a bit corresponding to said current page, when data of said current page is being modified according to groups of said bits flipping information of said lower pages, wherein a value of said bit corresponding to said current page is set as 1 if the binary correct value of said lower pages is smaller than the error value, and said value of said bit corresponding to said current page is set as 0 if the binary correct value of said lower pages is greater than the error value.
